(19) United States
(12) Patent Application Publication
(10) Pub. No.: US 2026/0239761 A1
(43) Pub. Date: Aug. 13, 2026

(54) SOLID-STATE IMAGE SENSOR INCLUDING PHASE DIFFERENCE DETECTION PIXEL

(71) Applicant: SAMSUNG ELECTRONICS CO., LTD., Suwon-si (KR)

(72) Inventors: Takaaki Shimomura, Yokohama-shi (JP); Kazufumi Shiozawa, Yokohama-shi (JP); Takayuki Ogasahara, Yokohama-shi (JP)

(73) Assignee: SAMSUNG ELECTRONICS CO., LTD., Suwon-si (KR)

(21) Appl. No.: 19/368,214

(22) Filed: Oct. 24, 2025

(30) Foreign Application Priority Data
Feb. 13, 2025 (JP) 2025-021187
May 15, 2025 (KR) 10-2025-0062935

(51) Int. Cl. H10F 39/00; H10F 39/18

(52) U.S. Cl. CPC H10F 39/8063; H10F 39/182; H10F 39/8057

(57) ABSTRACT

A solid-state image sensor includes a substrate comprising a first surface and a second surface opposing the first surface, a first image pixel comprising a first photodiode (PD), a second image pixel comprising a second PD, a phase difference detection pixel including a third PD and a fourth PD, and an anti-reflection layer on the third PD and the fourth PD. The anti-reflection layer includes a high refractive index layer group and a low refractive index layer group. A first refractive index layer of the high refractive index layer group includes a light separation slit, and the light separation slit includes a material having a different refractive index from the first refractive index layer. In a first direction perpendicular to the substrate, the first refractive index layer is the closest to the third PD and the fourth PD among the high refractive index layer group.

### CROSS-REFERENCE TO RELATED APPLICATIONS

This application is based on and claims benefit of priority to Japanese Patent Application No. 2025-021187 filed on Feb. 13, 2025 in the Japan Patent Office, and Korean Patent Application No. 10-2025-0062935 filed on May 15, 2025 in the Korean Intellectual Property Office, the disclosures of which are incorporated herein by reference in its entirety.

### BACKGROUND

### 1. Field

The disclosure relates to a solid-state image sensor including a phase difference detection pixel.

### 2. Description of Related Art

Related art electronic devices having an imaging function, such as a digital still camera, a smartphone, or the like, use solid-state image sensors such as a complementary metal oxide semiconductor (CMOS) image sensor or the like.

In a related art solid-state image sensor, as illustrated, for example, in Japanese Patent Application Publication No. 2015-12127, a device structure is provided in which a phase difference detection pixel capable of detecting an image phase difference is provided separately from a pixel generating an electric signal according to incident light on a pixel array.

### SUMMARY

In related art, a phase difference detection pixel has a problem in that, as a pixel array becomes finer, a separation ratio, which may be an indicator of autofocus performance, decreases due to a diffraction limit of incident light. In addition, the phase difference detection pixel has a problem of increasing color mixing or decreasing sensitivity (a decrease in quantum efficiency (QE)) by causing light scattering due to interaction between a pixel separation pattern and incident light on an incident surface of a photodiode.

In order to solve the problems, the phase difference detection pixel may form a boundary separation pattern partitioning the photodiode surrounded by the pixel separation pattern, but especially in a pixel size of less than 1 μm, a separation ratio is likely to decrease, so there may be room for improvement.

The disclosure has been made in consideration of the problems described above, and provides a solid-state image sensor capable of improving a separation ratio of incident light to the phase difference detection pixel. However, the disclosure is not limited thereto, and as such, the embodiments of the disclosure may address the above described problems and/or other problems.

According to an aspect of the disclosure, there is provided a solid-state image sensor including: a substrate comprising a first surface and a second surface opposing the first surface, a first image pixel comprising a first photodiode (PD), a second image pixel comprising a second PD, a phase difference detection pixel comprising a third PD and a fourth PD, a first lens on the first PD, a second lens on the second PD, a third lens on the third PD and the fourth PD, a boundary separation pattern between the third PD and the fourth PD, a first separation pattern between the first image pixel and the phase difference detection pixel, a second separation pattern between the second image pixel and the phase difference detection pixel, and an anti-reflection layer on the third PD and the fourth PD, wherein the first image pixel is disposed directly adjacent to the phase difference detection pixel, and the second image pixel is disposed directly adjacent to the phase difference detection pixel, wherein the anti-reflection layer comprises a high refractive index layer group and a low refractive index layer group, wherein the high refractive index layer group comprises at least one high refractive index layer and the low refractive index layer group comprises at least one low refractive index layer, wherein the anti-reflection layer is formed by alternately stacking the high refractive index layers of the high refractive index layer group and the low refractive index layers of the low refractive index layer group, wherein a first refractive index layer of the high refractive index layer group comprises a light separation slit, wherein the light separation slit comprises a material having a different refractive index from the first refractive index layer, and wherein, in a first direction perpendicular to the substrate, the first refractive index layer is the closest to the third PD and the fourth PD among the high refractive index layer group.

According to another aspect of the disclosure, there is provided a solid-state image sensor including: a substrate comprising a first surface and a second surface opposing the first surface, a phase difference detection pixel comprising a first PD and a second PD, a separation pattern surrounding the first PD and the second PD in a plan view and in contact with the second surface, a lens on the first and second PDs, a boundary separation pattern between the first PD and the second PD, and an anti-reflection layer on the first PD and the second PD, wherein the anti-reflection layer comprises a high refractive index layer group and a low refractive index layer group, wherein the high refractive index layer group comprises at least one high refractive index layer and the low refractive index layer group comprises at least one low refractive index layer, wherein the anti-reflection layer is formed by alternately stacking the high refractive index layers of the high refractive index layer group and the low refractive index layers of the low refractive index layer group, wherein a first refractive index layer of the high refractive index layer group comprises a light separation slit, wherein the light separation slit comprises a material having a different refractive index from the first refractive index layer, and wherein, in a first direction perpendicular to the substrate, the first refractive index layer is the closest to the first PD and the second PD among the high refractive index layer group.

According to another aspect of the disclosure, there is provided a solid-state image sensor including: a substrate comprising a first surface and a second surface opposing the first surface, a phase difference detection pixel comprising a first PD and a second PD, a lens on the first PD and the second PD, a boundary separation pattern between the first PD and the second PD, a separation pattern surrounding the first PD and the second PD in a plan view and in contact with the second surface, and an anti-reflection layer on the first PD and the second PD, wherein the anti-reflection layer comprises a first refractive index layer, a second refractive index layer on the first refractive layer, and a third refractive index layer on the second refractive index layer, wherein a refractive index of the first refractive index layer is different from a refractive index of the second refractive index layer, wherein a first refractive index layer comprises a light separation slit, wherein the light separation slit comprises a material having a different refractive index from the first refractive index layer, and wherein the light separation slit is overlapping with the boundary separation pattern in a first direction perpendicular to the substrate.

### BRIEF DESCRIPTION OF DRAWINGS

The and other aspects, features, and advantages of the embodiments of the disclosure will be more clearly understood from the following detailed description, taken in conjunction with the accompanying drawings, in which:

FIG. 1 is a block diagram illustrating a solid-state image sensor according to an embodiment.

FIG. 2 is a partially enlarged plan view of a solid-state image sensor according to an embodiment.

FIG. 3 is a cross-sectional schematic diagram partially cut of a solid-state image sensor according to an embodiment.

FIG. 4A is a schematic diagram illustrating a solid-state image sensor according to an embodiment when incident light is vertically incident.

FIG. 4B is a schematic diagram illustrating light intensity distribution of incident light vertically incident on a light separation slit in a solid-state image sensor according to an embodiment.

FIG. 4C is a schematic diagram illustrating light intensity distribution of incident light perpendicularly incident on a photodiode in a solid-state image sensor according to an embodiment.

FIG. 4D is a schematic diagram illustrating light intensity distribution of incident light perpendicularly incident on a photodiode in a solid-state image sensor according to another embodiment.

FIG. 5A is a schematic diagram illustrating light intensity distribution of incident light obliquely incident on a photodiode in a solid-state image sensor according to an embodiment.

FIG. 5B is a schematic diagram illustrating light intensity distribution of incident light obliquely incident on a photoelectric separation slit in a solid-state image sensor according to an embodiment.

FIG. 5C is a schematic diagram illustrating light intensity distribution of incident light obliquely incident on a photodiode in a solid-state image sensor according to an embodiment.

FIG. 5D is a cross-sectional schematic diagram illustrating a refraction state of incident light obliquely incident on a solid-state image sensor according to an embodiment.

FIG. 5E is a cross-sectional schematic diagram illustrating a refraction state of incident light obliquely incident on a solid-state image sensor that does not form a photoelectric separation slit.

FIG. 6A is a cross-sectional schematic diagram illustrating a light-gathering state of a solid-state image sensor having a light-gathering lens provided on an anti-reflection layer.

FIG. 6B is a cross-sectional schematic diagram illustrating a light-gathering state of a solid-state image sensor according to an embodiment.

FIG. 7A is a schematic diagram illustrating an example of a shape seen from a plane of a light separation slit in a case in which a photodiode is partitioned into two left and right portions in a horizontal direction.

FIG. 7B is a schematic diagram illustrating another example of a shape seen from a plane of a light separation slit in a case in which a photodiode is partitioned into two left and right portions in a horizontal direction.

FIG. 7C is a schematic diagram illustrating another example of a shape seen from a plane of a light separation slit in a case in which a photodiode is partitioned into two left and right portions in a horizontal direction.

FIG. 7D is a schematic diagram illustrating another example of a shape seen from a plane of a light separation slit in a case in which a photodiode is partitioned into two left and right portions in a horizontal direction.

FIG. 8A is a schematic diagram illustrating an example of a shape seen from a plane of a light separation slit in a case in which a photodiode is partitioned into two upper and lower portions in a vertical direction.

FIG. 8B is a schematic diagram illustrating another example of a shape seen from a plane of a light separation slit in a case in which a photodiode is partitioned into two upper and lower portions in a vertical direction.

FIG. 8C is a schematic diagram illustrating another example of a shape seen from a plane of a light separation slit in a case in which a photodiode is partitioned into two upper and lower portions in a vertical direction.

FIG. 9A is a schematic diagram illustrating an example of a shape seen from a plane of a light separation slit in a case in which a photodiode is partitioned into four portions.

FIG. 9B is a schematic diagram illustrating another example of a shape seen from a plane of a light separation slit in a case in which a photodiode is partitioned into four portions.

FIG. 9C is a schematic diagram illustrating another example of a shape seen from a plane of a light separation slit in a case in which a photodiode is partitioned into four portions.

FIG. 9D is a schematic diagram illustrating another example of a shape seen from a plane of a light separation slit in a case in which a photodiode is partitioned into four portions.

FIG. 9E is a schematic diagram illustrating another example of a shape seen from a plane of a light separation slit in a case in which a photodiode is partitioned into four portions.

FIG. 9F is a schematic diagram illustrating another example of a shape seen from a plane of a light separation slit in a case in which a photodiode is partitioned into four portions.

FIG. 9G is a schematic diagram illustrating another example of a shape seen from a plane of a light separation slit in a case in which a photodiode is partitioned into four portions.

FIG. 9H is a schematic diagram illustrating another example of a shape seen from a plane of a light separation slit in a case in which a photodiode is partitioned into four portions.

FIG. 10A is a schematic diagram illustrating another example of a shape seen from a plane of a light separation slit in a case in which a photodiode is partitioned into two left and right portions in a horizontal direction.

FIG. 10B is a schematic diagram illustrating another example of a shape seen from a plane of a light separation slit in a case in which a photodiode is partitioned into two left and right portions in a horizontal direction.

FIG. 10C is a schematic diagram illustrating another example of a shape seen from a plane of a light separation slit in a case in which a photodiode is partitioned into two left and right portions in a horizontal direction.

FIG. 10D is a schematic diagram illustrating another example of a shape seen from a plane of a light separation slit in a case in which a photodiode is partitioned into two left and right portions in a horizontal direction.

FIG. 11A is a schematic diagram illustrating another example of a shape seen from a plane of a light separation slit in a case in which a photodiode is partitioned into four portions.

FIG. 11B is a schematic diagram illustrating another example of a shape seen from a plane of a light separation slit in a case in which a photodiode is partitioned into four portions.

FIG. 11C is a schematic diagram illustrating another example of a shape seen from a plane of a light separation slit in a case in which a photodiode is partitioned into four portions.

FIG. 11D is a schematic diagram illustrating another example of a shape seen from a plane of a light separation slit in a case in which a photodiode is partitioned into four portions.

FIG. 12A is a cross-sectional schematic diagram illustrating an example of a shape of a cross-section of a light separation slit.

FIG. 12B is a cross-sectional schematic diagram illustrating another example of a shape of a cross-section of a light separation slit.

FIG. 12C is a cross-sectional schematic diagram illustrating another example of a shape of a cross-section of a light separation slit.

FIG. 13A is a schematic diagram of a phase difference detection pixel provided on a low deviated side in a solid-state image sensor according to another embodiment.

FIG. 13B is a cross-sectional schematic diagram of the phase difference detection pixel illustrated in FIG. 13A, taken along line A-A.

FIG. 14A is a schematic diagram of a phase difference detection pixel provided on a high deviated side in a solid-state image sensor according to another embodiment.

FIG. 14B is a cross-sectional schematic diagram of the phase difference detection pixel illustrated in FIG. 14A, taken along line B-B.

FIG. 15A is a schematic diagram of a phase difference detection pixel provided on a low deviated side in a solid-state image sensor according to another embodiment.

FIG. 15B is a cross-sectional schematic diagram of the phase difference detection pixel illustrated in FIG. 15A, taken along line C-C.

FIG. 16A is a schematic diagram of a phase difference detection pixel provided on a high deviated side in a solid-state image sensor according to another embodiment.

FIG. 16B is a cross-sectional schematic diagram of the phase difference detection pixel illustrated in FIG. 16A, taken along line D-D.

FIG. 17A is a cross-sectional schematic diagram illustrating an example of a shape of a light separation slit in a solid-state image sensor according to another embodiment.

FIG. 17B is a cross-sectional schematic diagram illustrating another example of a shape of a light separation slit in a solid-state image sensor according to another embodiment.

FIG. 17C is a cross-sectional schematic diagram illustrating another example of a shape of a light separation slit in a solid-state image sensor according to another embodiment.

FIG. 18A is a schematic diagram of a solid-state image sensor according to Example Embodiment.

FIG. 18B is a cross-sectional schematic diagram of a high refractive index layer on which a light separation slit is formed in a phase difference detection pixel of Example Embodiment.

FIG. 19A is a schematic diagram of a solid-state image sensor of Comparative Example.

FIG. 19B is a schematic diagram of a cross-section of a high refractive index layer in a phase difference detection pixel of Comparative Example.

FIG. 20 is a graph illustrating simulation results of Example Embodiment.

### DETAILED DESCRIPTION

Hereinafter, with reference to the attached drawings, embodiments will be described in detail. In the drawings below, the same reference numerals indicate the same components, and in the drawings, a size of each of the components may be exaggerated for clarity and convenience of explanation. In addition, embodiments described below are merely illustrative, and various modifications are possible from such embodiments.

Hereinafter, the terms “on,” “above,” or “on or above” may include not only those directly above in contact, but also those directly above in non-contact. Similarly, the terms “below” or “on or below” may include not only those directly below in contact, but also those directly below in non-contact.

A singular expression may include a plural expression, unless the context clearly indicates that it is singular. In addition, when a portion is said to “comprise,” “include,” “provide,” or “have” a component, this may mean that other components may be additionally included, rather than excluding other components, unless otherwise specifically stated.

With respect to operations constituting a method, when an order is explicitly stated or when there is no other description, the operations constituting the method may be performed in an appropriate order. It may not be necessarily limited to an order of the operations described. All examples or illustrative terms may be used only to explain technical ideas, and the scope is not limited by the examples or illustrative terms, unless otherwise specified by the claims.

In the following descriptions, when ordinal numerals such as “first” and “second” are attached for explanation, they may be used for convenience and do not specify any order, unless specifically stated.

A description will be given of a configuration of a solid-state image sensor 1 according to an embodiment.

In this case, for the convenience of explanation, an XYZ orthogonal coordinate system may be set for the solid-state image sensor 1. A direction parallel to an X-axis in a given plane is referred to as an X-axis direction. A direction parallel to a Y-axis, orthogonal to the X-axis, in the given plane, is referred to as a Y-axis direction. A direction parallel to a Z-axis, orthogonal to the X-axis and the Y-axis, is referred to as a Z-axis direction. According to one or more embodiments, the given plane may be parallel to the horizontal plane in an X-Y plane, and the Z-axis may be a vertical direction, orthogonal to the given plane. Therefore, the Z-axis direction may correspond to a stacking direction (or thickness direction) of each component constituting the solid-state image sensor 1, and the X-axis direction and the Y-axis direction may correspond to a plane direction, orthogonal to the stacking direction.

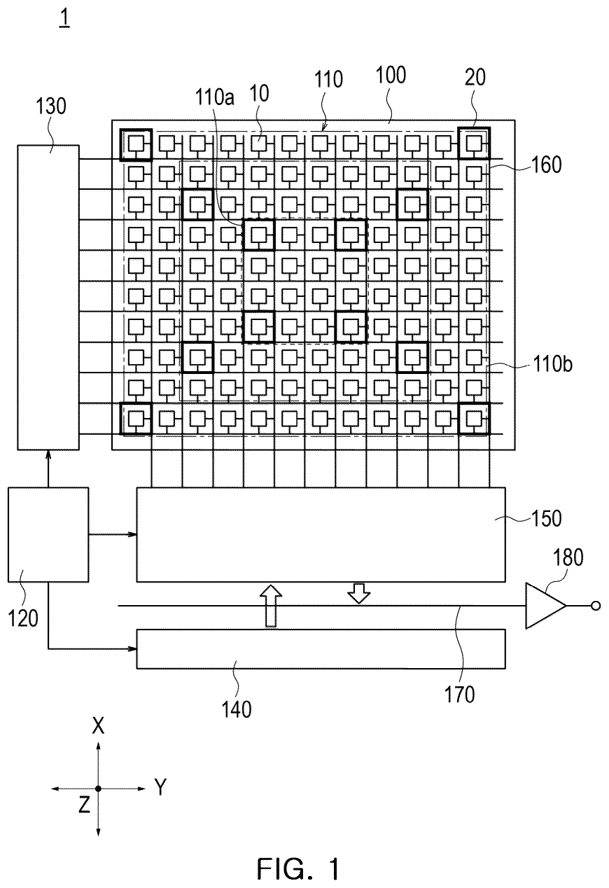

As illustrated in FIG. 1, the solid-state image sensor 1 may include a pixel 10, a phase difference detection pixel 20, and a chip substrate 100. The solid-state image sensor 1 may be formed as a CMOS image sensor.

For example, the solid-state image sensor 1 may have a pixel array 110 formed of a plurality of pixels 10 outputting a pixel signal on the chip substrate 100 and at least one phase difference detection pixel 20 capable of detecting an image phase difference. The solid-state image sensor 1 may including a control circuit 120 configured to generate an operating signal for respectively operating a circuit or a pixel, a vertical drive circuit 130 configured to scan each of the pixels 10 in the vertical direction (Y-axis direction in the drawings), which may be a second direction, orthogonal to a first direction, and control output of a pixel signal according to an amount of light received by each of the pixels 10, a horizontal drive circuit 140 configured to output a scanning pulse in the horizontal direction (X-axis direction in the drawing), which may be the first direction, a column signal processing circuit 150 configured to process a pixel signal output from each of the pixels 10 and generate an image signal, a vertical signal line 160 configured to transmit a pixel signal generated from each of the pixels 10 to the column signal processing circuit 150, a horizontal signal line 170 configured to output an image signal from the column signal processing circuit 150, and an output circuit 180 connected to the horizontal signal line 170 and configured to process the received image signal and output a signal after the processing. In FIG. 1, a region surrounded by a thick line in the pixel array 110 represents the phase difference detection pixel 20.

In addition, a central portion 110a of the pixel array 110 may refer to a predetermined range from a center of the pixel array 110 toward an outer periphery, as illustrated in FIG. 1, and a peripheral portion 110b of the pixel array 110 may refer to a predetermined range from an outermost periphery of the pixel array 110 toward the central portion. According to one or more embodiments of the disclosure, a ‘low deviated side’ of the pixel array 110 may refer to the central portion 110a or a portion adjacent to the central portion 110a, and a ‘high deviated side’ of the pixel array 110 may refer to a portion spaced from the central portion 110a toward the outer periphery, or a portion adjacent to the outermost periphery of the pixel array 110.

The chip substrate 100 may be formed of silicon (Si) or the like, and the pixels 10 and the phase difference detection pixels 20 may be formed on the chip substrate. According to an embodiment, a photodiode of the pixel 10 and a photodiode 25 of the phase difference detection pixel 20 may be configured on the chip substrate 100. According to an embodiment, in the chip substrate 100, one or more other components, including, but not limited to, a pixel transistor, an interconnection layer, or the like, may be formed on a surface opposite to an incident surface of light (hereinafter, also referred to as “incident light L”) incident on the solid-state image sensor 1. The chip substrate 100 may output a pixel signal in which the incident light L received by the pixel 10 and the phase difference detection pixel 20 is converted into an electric signal, to the control circuit 120 or the like. According to an example embodiment, each of the plurality of pixels 10 and each of the plurality of phase difference detection pixels 20 may include a plurality of transistors. In another embodiment, two or more adjacent pixels 10 may form a pixel group, and the two or more pixels 10 belonging to the pixel group may share at least a portion of a transfer transistor, a source power transistor, a selection transistor, and a reset transistor.

The solid-state image sensor 1 may optionally and selectively employ any known configuration in the technical field of solid-state image sensors, other than the phase difference detection pixel 20 formed in the pixel array 110. For convenience and brevity, a detailed description of the components other than the phase difference detection pixel 20 may be omitted.

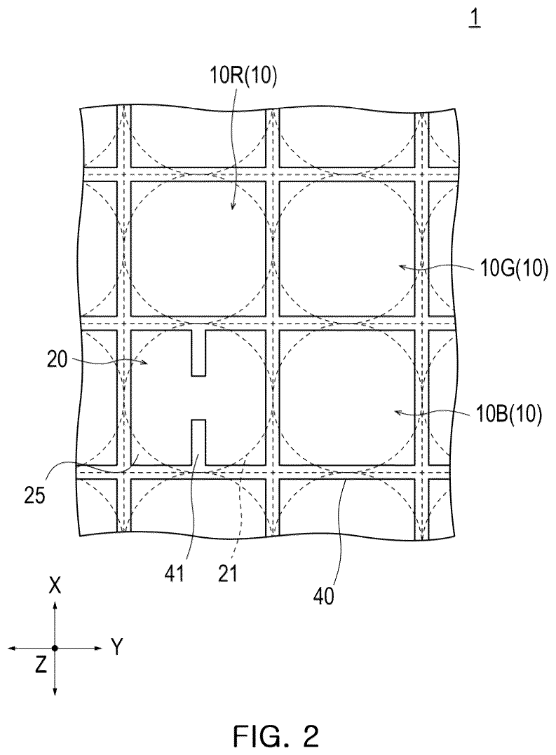

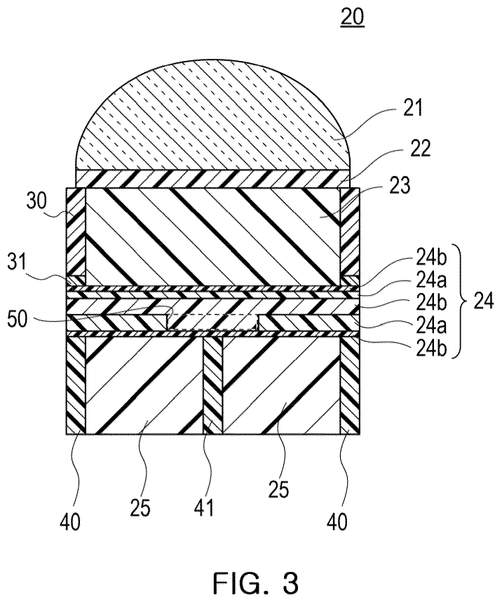

FIG. 2 illustrates a partially enlarged plan view of a solid-state image sensor 1 of an embodiment cut in the horizontal direction (or cut in the X-Y plane). FIG. 3 illustrates a schematic cross-sectional view of a solid-state image sensor 1 partially cut.

As illustrated in FIG. 2, a pixel 10 may include a red pixel 10R, a green pixel 10G, and a blue pixel 10B. Pixels 10 may be provided in a two-dimensional shape (for example, in a matrix shape) on a chip substrate 100. In a pixel array 110, the pixel 10 and a phase difference detection pixel 20 may be provided in a Bayer pattern. However, this is illustrative, and the pixel array 110 may also include a yellow filter, a magenta filter, and a cyan filter. In addition, arrangement positions of the pixels 10 and the phase difference detection pixels 20 in the pixel array 110 and the number of arrangements of each of the pixels may be variously modified.

As illustrated in FIG. 3, a phase difference detection pixel 20 may include an on-chip lens 21, a planarization layer 22, a light-transmitting layer 23, an anti-reflection layer 24, a photodiode 25, a light-transmitting layer separation pattern 30, a pixel separation pattern 40, and a light separation slit 50. The phase difference detection pixel 20 may be partitioned by the light-transmitting layer separation pattern 30 or the pixel separation pattern 40, and may be separated independently from an adjacent pixel 10 or an adjacent phase difference detection pixel 20, respectively.

Referring to FIGS. 2 and 3, the phase difference detection pixel 20 may have a structure in which the photodiode 25 is partitioned into a plurality of portions by a boundary separation pattern 41. The phase difference detection pixel 20 may detect a phase difference from a difference in pixel signal, based on amounts of charges generated by the plurality of photodiodes 25, to calculate a degree of focus misalignment, and may move a camera lens based on calculation results therefrom to realize autofocus. Therefore, an imaging device equipped with the solid-state image sensor 1 may focus on a subject based on a phase difference of light incident on the phase difference detection pixel 20 without a dedicated autofocus mechanism.

The on-chip lens 21 may be formed on the planarization layer 22. The on-chip lens 21 may be provided to correspond to the phase difference detection pixel 20. For example, the on-chip lens 21 may be arranged two-dimensionally (for example, in a matrix shape) on a plane. The on-chip lens 21 may have a convex shape and a radius of curvature such that incident light L may be focused on the photodiode 25. The radius of curvature may be predetermined. The on-chip lens 21 may be formed using an organic material such as a styrene-based resin, an acrylic-based resin, a styrene-acrylic copolymer-based resin, a siloxane-based resin, or the like, for example.

The planarization layer 22 may be formed between the on-chip lens 21 and the light-transmitting layer 23. The planarization layer 22 may have a high transmittance for the incident light L on the photodiode 25, and may provide a flat surface for the on-chip lens 21. The planarization layer 22 may be formed of an organic material such as a resin or the like, for example.

The light-transmitting layer 23 may be formed between the planarization layer 22 and the photodiode 25, and may be arranged two-dimensionally (for example, in a matrix shape) to correspond to unit pixels, respectively. The light-transmitting layer 23 may be formed by including a pigment, a dye, or the like of a desired color in a resin with low light absorption. A refractive index of the light-transmitting layer 23 may be 1.6 or greater and 1.8 or less.

The light-transmitting layer 23 may transmit light of a specific wavelength in the visible light range. For example, the light-transmitting layer 23 may serve as a color filter. For example, the light-transmitting layer 23 may be configured to transmit one of red light, green light, or blue light as light of a specific wavelength, and absorbs other light. In addition, the light-transmitting layer 23 may function as a so-called white filter transmitting light of a specific wavelength and an approximate entire visible light range. For example, the light-transmitting layer 23 may be a transparent layer transmitting light of all colors included in the visible light range as the white filter.

In the light-transmitting layer 23, the light-transmitting layer separation pattern 30 having light-blocking properties may be formed in a boundary portion with another adjacent light-transmitting layer 23. Therefore, the light-transmitting layer 23 may be separated from an adjacent pixel 10 or an adjacent phase difference detection pixel 20.

The anti-reflection layer 24 may be formed between the light-transmitting layer 23 and the photodiode 25. The anti-reflection layer 24 may be formed by alternately stacking a high refractive index layer 24a and a low refractive index layer 24b. For example, the high refractive index layer 24a has a refractive index higher than the low refractive index layer 24 b. For example, a refractive index of the high refractive index layer 24a may be 1.9 or greater and 2.6 or less. For example, a refractive index of the low refractive index layer 24b may be 1.3 or greater and 1.5 or less. For example, the high refractive index layer 24a may be formed of a high refractive index material including, but not limited to, silicon nitride (SiN), hafnium oxide (HfO), tantalum oxide (TaO), titanium oxide (TiO), or the like, and the low refractive index layer 24b may be formed of a low refractive index material including, but not limited to, silicon oxide (SiO₂), aluminum oxide (AlO), or the like.

The anti-reflection layer 24 may be formed by alternately stacking the low refractive index layer 24b and the high refractive index layer 24a from an incident side of incident light L, for example, as illustrated in FIG. 3. The high refractive index layer 24a may be formed of the same material or different materials in each layer to be stacked. The low refractive index layer 24b may be formed of the same material or different materials in each layer to be stacked. The anti-reflection layer 24 illustrated in FIG. 3 may have a stack structure formed of five layers, in sequence from the incident side of the incident light L, of the low refractive index layer 24b, the high refractive index layer 24a, the low refractive index layer 24b, the high refractive index layer 24a, and the low refractive index layer 24b. According to an embodiment, the anti-reflection layer 24 may include any number of high refractive index layers 24a and low refractive index layers 24b to be stacked. According to an embodiment, in the anti-reflection layer 24, an uppermost layer and a lowermost layer are at least the low refractive index layer 24b.

The photodiode 25 may convert transmitted light of a photoelectric conversion target incident on the photodiode 25, among the incident light L, into an electric signal. The photodiode 25 has a structure in which the photodiode 25 is partitioned into a plurality of portions by the boundary separation pattern 41. The photodiode 25 may include, for example, at least one of a photoelectric converter, a photo transistor, a photo gate, a pinned photo diode, an organic photo diode, a quantum dot, or a combination thereof, but is not limited thereto.

The light-transmitting layer separation pattern 30 may be formed to surround the light-transmitting layer 23 in the phase difference detection pixel 20. The light-transmitting layer separation pattern 30 may be provided in a grid shape, when viewed from a plane, may form a boundary between adjacent pixels 10 to partition and separate each layer into a predetermined size. The light-transmitting layer separation pattern 30 may have, at least, a function of preventing a vignetting phenomenon of the incident light L incident on the phase difference detection pixel 20, and a function of blocking light coming from an adjacent pixel 10. Therefore, the light-transmitting layer separation pattern 30 may be formed, with a height and a width, satisfying these functions. For example, the light-transmitting layer separation pattern 30 may be configured to prevent a vignetting phenomenon of the incident light L incident on the phase difference detection pixel 20, and block light from an adjacent pixel 10. The light-transmitting layer separation pattern 30 may be formed as a dielectric material having low light absorption, such as silicon oxide (SiO₂), silicon nitride (SiN), or the like.

A light-blocking portion 31 may be formed between the light-transmitting layer separation pattern 30 and the anti-reflection layer 24. The light-blocking portion 31 may be formed to surround the light-transmitting layer 23. The light-blocking portion 31 may be provided between adjacent pixels 10 or phase difference detection pixels 20, may suppress crosstalk between adjacent pixels, and may further improve accuracy during phase difference detection. The light-blocking portion 31 may be formed of a metal material, such as titanium nitride (TiN), titanium (Ti), tungsten (W), aluminum (Al), molybdenum (Mo), nickel (Ni), or the like.

The pixel separation pattern 40 may be formed with deep trench isolation (DTI). The pixel separation pattern 40 may be formed to surround the photodiode 25 of the phase difference detection pixel 20, as illustrated in FIGS. 2 and 3. Therefore, the photodiodes 25 of the phase difference detection pixels 20 may be individually separated from each other.

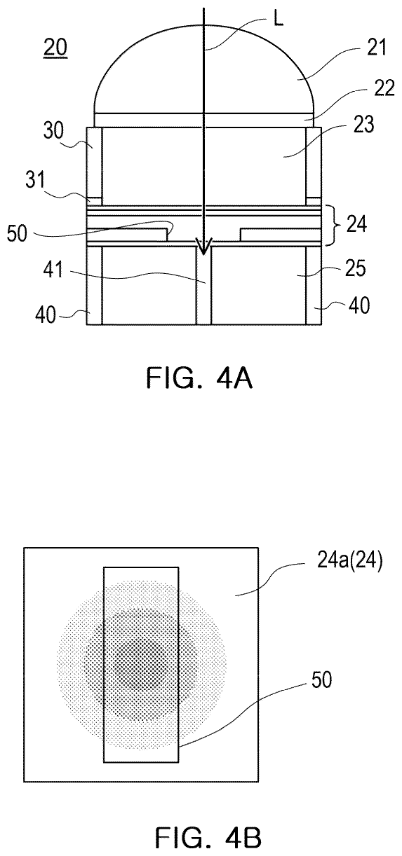

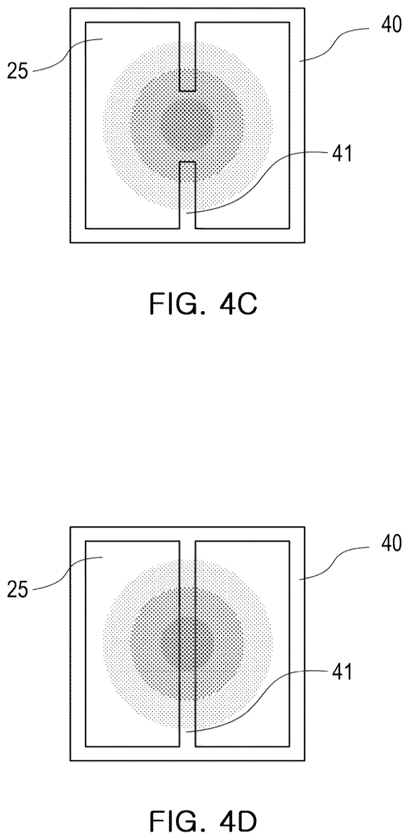

The pixel separation pattern 40 may have the boundary separation pattern 41 partitioning the photodiode 25 into a plurality of portions. The boundary separation pattern 41 may partition the photodiode 25 into a predetermined number of portions such that the photodiode 25 may detect an upper surface phase difference in the phase difference detection pixel 20. In this case, the term “partitioning” may include, for example, a structure in which a portion of the photodiode 25 is partitioned and separated as illustrated in FIG. 4C, as well as a structure in which the photodiode 25 is completely partitioned and separated by connecting the boundary separation pattern 41, as illustrated in FIG. 4D, to terminate the photodiode 25.

The solid-state image sensor 1 according to an embodiment, as illustrated in FIG. 3, the light separation slit 50 may be formed in a high refractive index layer 24a provided to be closest to the photodiode 25, among the high refractive index layers 24a constituting the anti-reflection layer 24. The light separation slit 50 may be a region surrounded by a dotted line in FIG. 3 (a region between the high refractive index layers 24a on the left and right).

As illustrated in FIG. 3, the light separation slit 50 may be formed in a portion of the high refractive index layer 24a, and may have a slit structure improving a separation ratio (separation characteristics) of incident light L. As illustrated in FIG. 3, the light separation slit 50 may penetrate the high refractive index layer 24a, and may be formed continuously with the low refractive index layer 24b, which is the lowest low refractive index layer 24b the anti-reflection layer 24. For example, the light separation slit 50 may be provided in the high refractive index layer 24a immediately (or directly) above the lowest low refractive index layer 24b of the anti-reflection layer 24. The light separation slit 50 may be formed of the same material as the low refractive index layer 24b, or may be formed of a low refractive index material different from the low refractive index layer 24b.

In an example case in which the light separation slit 50 is provided in a central portion of the phase difference detection pixel 20 and the high refractive index layer 24a may be formed therearound, the light separation slit 50 may exert the following effects depending on an incident angle of the incident light L.

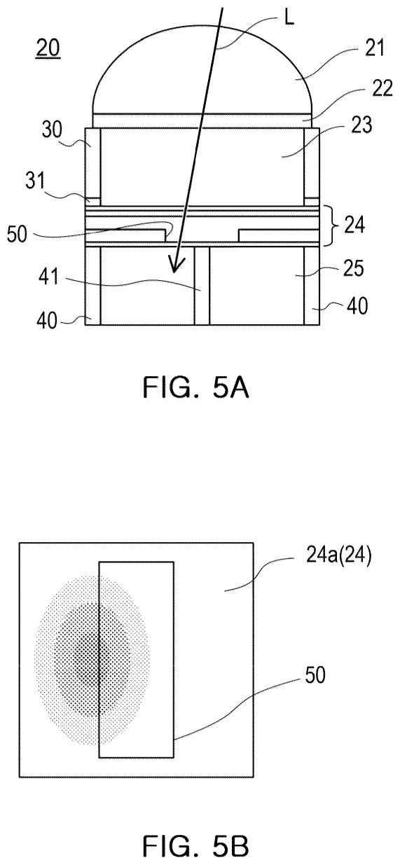

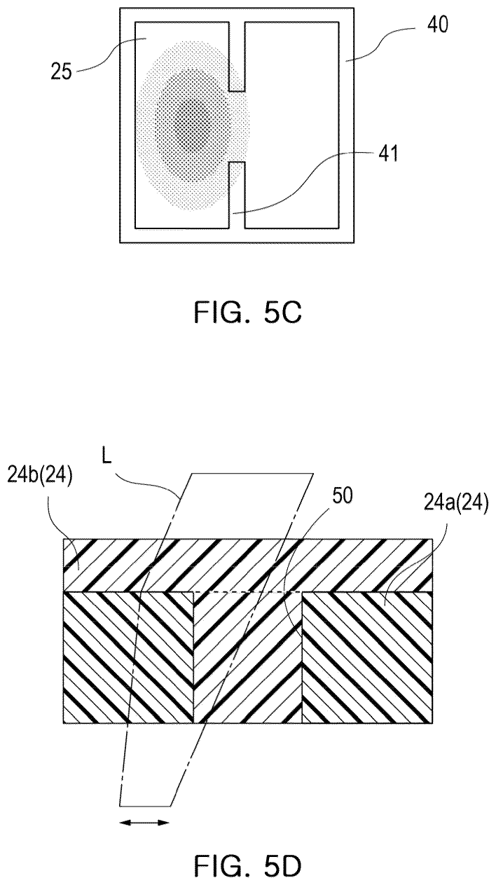

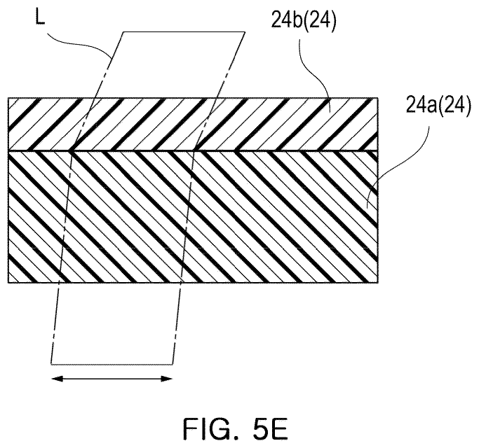

In an example case in which incident light L is vertically incident, as illustrated in FIG. 4A, a light separation slit 50 may have a slit structure symmetrical left and right with respect to light intensity distribution, as illustrated in FIGS. 4B and 4C. Gradient regions of dot hatches illustrated in FIGS. 4B, 4C, 5B, and 5C schematically represent light intensity distribution of the incident light L. In each of the drawings, the light intensity distribution illustrates that light intensity increases from a region with lighter dots (or a region with lower dot density) to a region with darker dots (or a region with higher dot density).

In an example case in which incident light L is obliquely incident, as illustrated in FIG. 5A, light intensity distribution may be biased toward a high refractive index layer 24a, as illustrated in FIGS. 5B and 5C. As illustrated in FIG. 5D, since a light separation slit 50 may be formed of a low refractive index material, among the incident light L (single-dotted line in the drawings), light passing through the light separation slit 50, may proceed straight without refraction, and light passing through the high refractive index layer 24a therearound may be refracted. Therefore, the incident light L may be focused such that a width thereof narrows toward a photodiode 25. FIG. 5E illustrates a refractive state of incident light L (single-dotted line in the drawing) obliquely incident on a solid-state image sensor not forming a light separation slit. In a related art solid-state image sensor, since a light separation slit 50 may not be formed, as illustrated in FIG. 5E, light may be entirely refracted and not focused due to action of a high refractive index layer 24a. Comparing a configuration of FIG. 5D with a configuration of FIG. 5E, it can be seen that a solid-state image sensor having a light separation slit 50 illustrated in FIG. 5D focuses incident light L on one side of a device. In this manner, the light separation slit 50 may be formed in a central portion of a pixel to be focused on one side of a device (e.g., one side of a photodiode 25), as illustrated in FIG. 5D. Therefore, a phase difference detection pixel 20 equipped with the light separation slit 50 may focus the incident light L to bias light intensity distribution with respect to the photodiode 25, thereby improving a separation ratio.

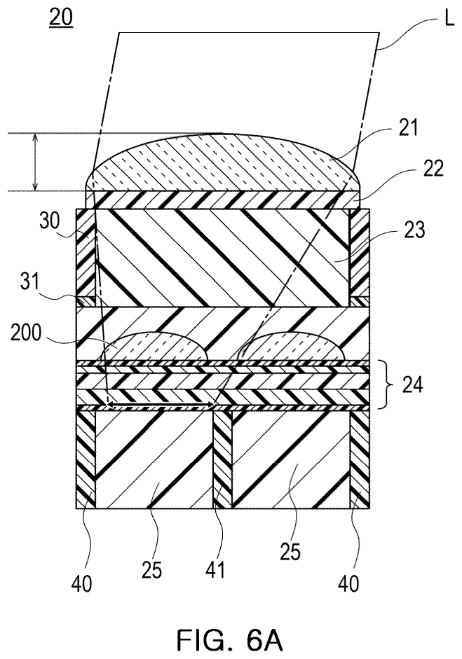

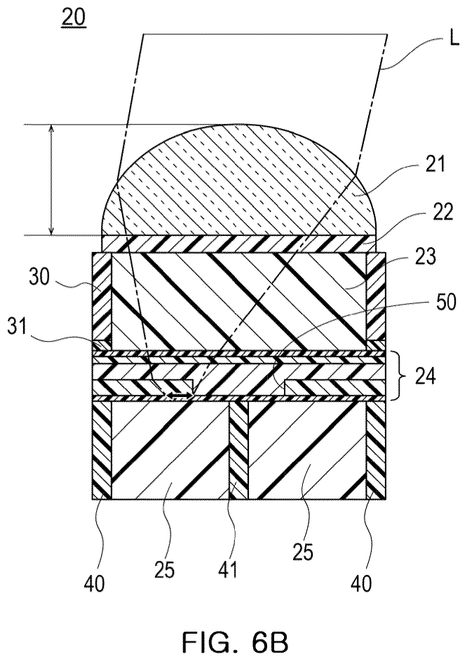

In an example case in which a phase difference detection pixel 20 is provided to improve a separation ratio with a configuration other than the light separation slit 50, a configuration in which a light-collecting lens 200 is stacked and provided on an anti-reflection layer 24 respectively corresponding to photodiodes 25 may be considered, as illustrated in FIG. 6A. In the phase difference detection pixel 20 illustrated in FIG. 6A, the light-collecting lens 200 may be provided such that a pixel structure may have a high profile formation, a thick thickness, or a large size, and a radius of curvature of the on-chip lens 21 should be reduced to focus light on the photodiode 25. As a result, a diameter of a light-collecting spot of the phase difference detection pixel 20 tends to become larger. In contrast, since a solid-state image sensor 1 of an embodiment, as illustrated in FIG. 6B, does not require an extra configuration such as a light-collecting lens 200 or the like due to a slit structure by a light separation slit 50, a pixel structure may be made a low profile formation, a thin thickness, or a small size. Therefore, the solid-state image sensor 1 may have an on-chip lens 21 with a higher radius of curvature than that in FIG. 6A, as illustrated in FIG. 6B, and a diameter of a light-collecting spot may decrease to effectively improve a separation ratio or sensitivity.

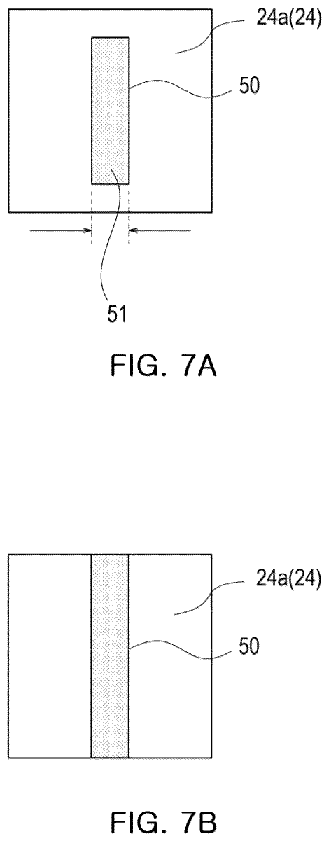

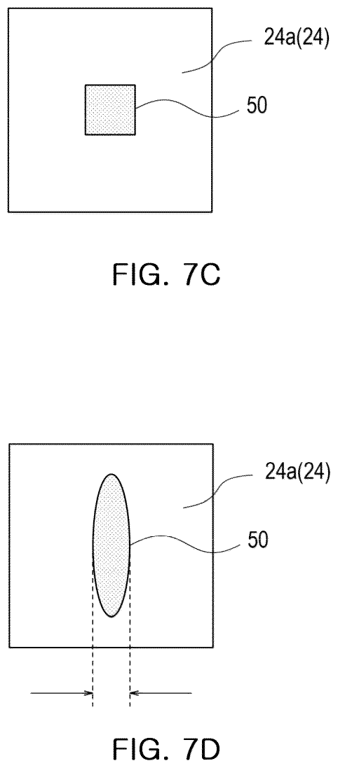

A light separation slit 50 may be formed of various shapes that may exert a light collection effect in a high refractive index layer 24a depending on the number or arrangement of a plurality of portions separated from each other of a photodiode 25. The light separation slit 50 may have a shape as seen in a plane as illustrated in FIGS. 7A to 7D, FIGS. 8A to 8C, FIGS. 9A to 9H, FIGS. 10A to 10D, and FIGS. 11A to 11D.

FIGS. 7A to 7D illustrate examples of a shape seen from a plane of a light separation slit 50 in a case in which a photodiode 25 is partitioned into two portions (e.g., left and right portions) in the horizontal direction. As illustrated in FIGS. 7A to 7D, in an example case in which the photodiode 25 is partitioned into two left and right portions in the horizontal direction, the light separation slit 50 may have a shape seen from a plane as, for example, a rectangular shape as illustrated in FIG. 7A, a straight line as illustrated in FIG. 7B, a square shape as illustrated in FIG. 7C, an elliptical shape as illustrated in FIG. 7D, or the like. The light separation slit 50 illustrated in FIGS. 7A, 7B, and 7D may be formed by extending in the vertical direction in accordance with a separation shape of the photodiode 25.

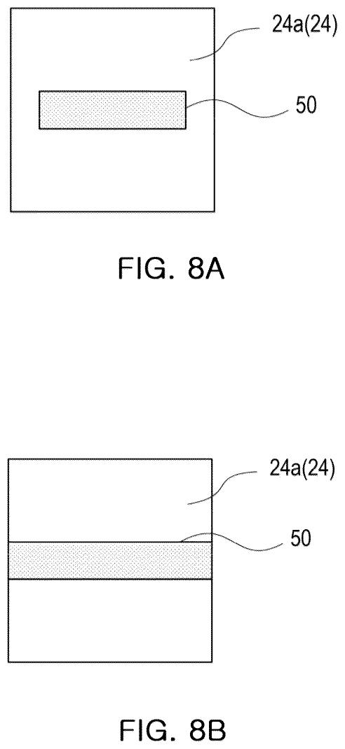

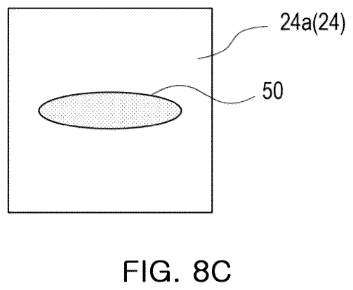

FIGS. 8A to 8C illustrate examples of a shape seen from a plane of a light separation slit 50 in a case in which a photodiode 25 is partitioned into two portions (e.g., upper and lower portions) in the vertical direction. As illustrated in FIGS. 8A to 8C, in an example case in which the photodiode 25 is partitioned into two upper and lower portions in the vertical direction, the light separation slit 50 may have a shape as viewed from the plane, such as a rectangular shape as illustrated in FIG. 8A, a straight line as illustrated in FIG. 8B, an elliptical shape as illustrated in FIG. 8C, or the like. In an example case in which the photodiode 25 is partitioned into two upper and lower portions in the vertical direction, the light separation slit 50 may also adopt a square shape as illustrated in FIG. 7C. The light separation slit 50 illustrated in FIGS. 8A, 8B, and 8C may be formed by extending in the horizontal direction in accordance with a separation shape of the photodiode 25.

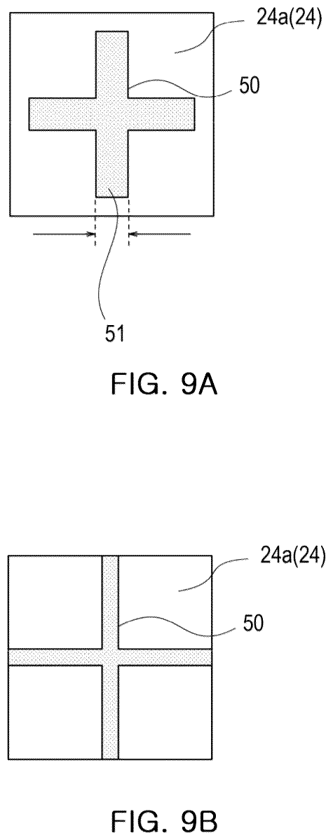

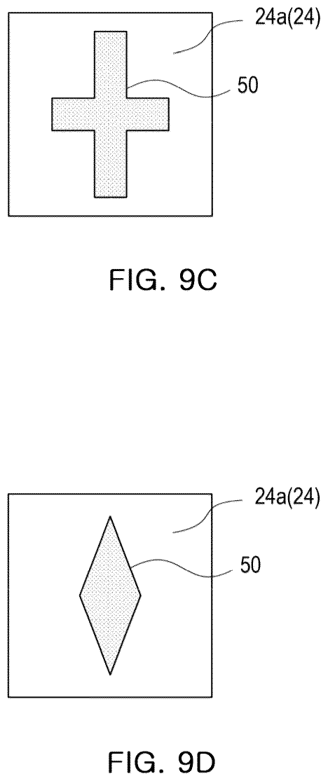

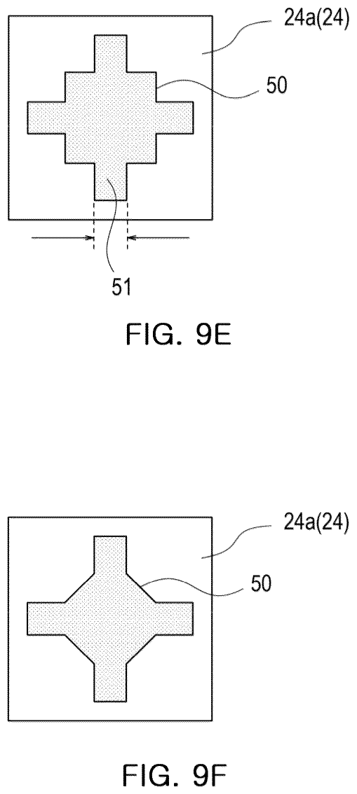

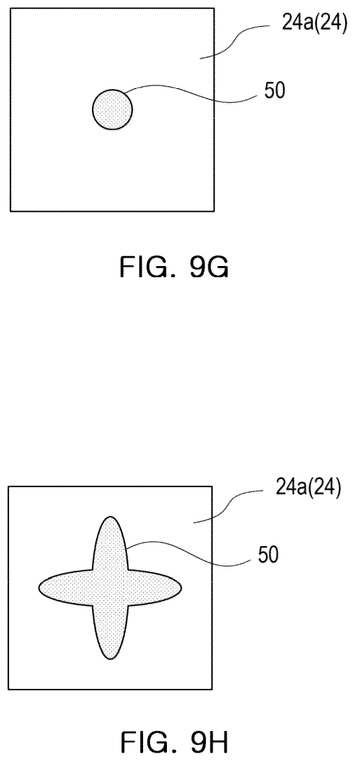

FIGS. 9A to 9H illustrate examples of a shape seen from a plane of a light separation slit 50 in a case in which a photodiode 25 is partitioned into four portions. As illustrated in FIGS. 9A to 9H, in an example case in which the photodiode 25 is partitioned into four portions, the light separation slit 50 may have a shape seen from a plane as, for example, a cross shape as illustrated in FIG. 9A, two orthogonal straight lines as illustrated in FIG. 9B, a vertically elongated cross shape as illustrated in FIG. 9C, a diamond shape as illustrated in FIG. 9D, a shape combining a square shape and a cross shape as illustrated in FIG. 9E, a shape combining a diamond shape and a cross shape as illustrated in FIG. 9F, a circle shape as illustrated in FIG. 9G, an elliptical cross shape as illustrated in FIG. 9H, or the like. The shapes illustrated in FIGS. 9E, 9F, and 9H may be shapes in which center points of one shape and the other shape overlap. For example, the “elliptical cross shape” illustrated in FIG. 9H may be a shape in which two ellipses in which shapes in a plane are equal and common center points overlap such that a long axis of one is orthogonal to a long axis of the other.

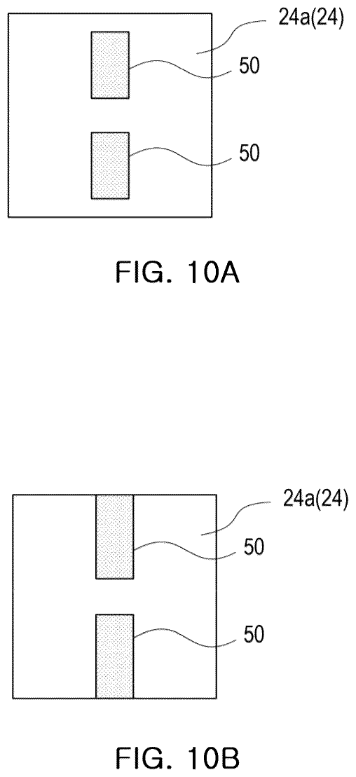

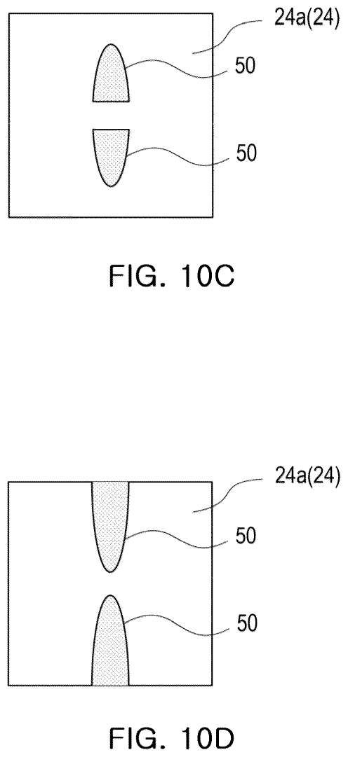

FIGS. 10A to 10D illustrate other examples of a shape seen from a plane of a light separation slit in a case in which a photodiode is partitioned into two portions. As illustrated in FIGS. 10A to 10D, a light separation slit 50 may also be a shape in which a high refractive index layer 24a is left in a region to be a light-collecting portion of incident light L transmitted through an on-chip lens 21 as a shape seen from a plane in an example case in which a photodiode 25 is partitioned into two left and right portions in the horizontal direction, as a modified example of FIG. 7. FIG. 10A may be a shape in which a region to be a light-collecting portion in a rectangular shape is formed as the high refractive index layer 24a. FIG. 10B may be a shape in which a region to be a light-collecting portion in a straight line is formed as the high refractive index layer 24a. FIG. 10C may be a shape in which a region to be a light-collecting portion in an elliptical shape is formed as the high refractive index layer 24a. FIG. 10D may be another shape in which vertices of a major axis direction of an elliptical shape partitioned into two are provided to face each other and a region to be a light-collecting portion is formed as the high refractive index layer 24a.

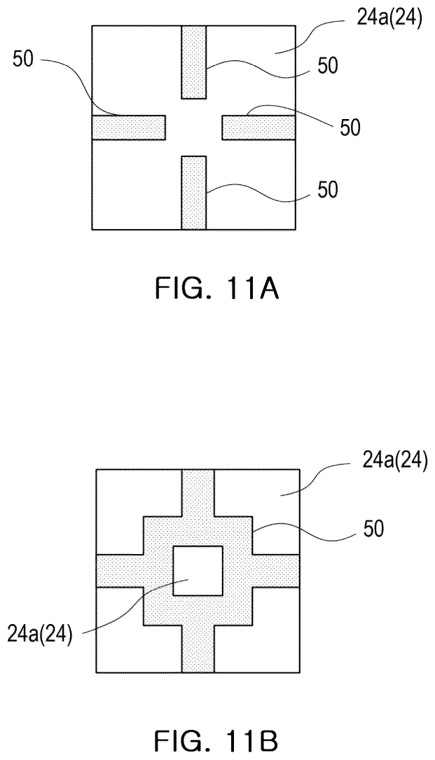

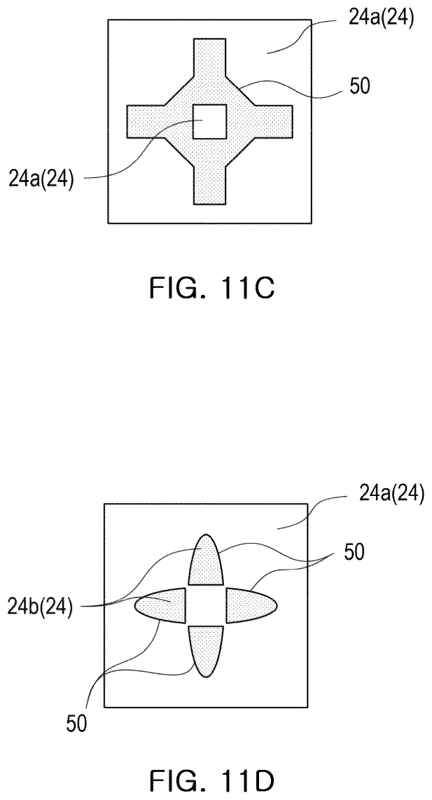

FIGS. 11A to 11D illustrate other examples of a shape seen from a plane of a light separation slit in a case in which a photodiode is partitioned into four portions. As illustrated in FIGS. 11A to 11D, a light separation slit 50 may also be a shape in which a high refractive index layer 24a is left in a region to be a light-collecting portion of an on-chip lens 21 as a shape seen from a plane in an example case in which a photodiode 25 is partitioned into four portions, as a modified example of FIG. 9. FIG. 11A may be a shape in which a region to be a light-collecting portion in a cross shape is formed as the high refractive index layer 24a. FIG. 11B may be a shape in which a region to be a light-collecting portion in a shape combining a square shape and a cross shape is formed as the high refractive index layer 24a. FIG. 11C may be a shape in which a region to be a light-collecting portion in a shape combining a diamond shape and a cross shape is formed as the high refractive index layer 24a. FIG. 11D may be a shape in which a region to be a light-collecting portion in an elliptical cross shape is formed as the high refractive index layer 24a.

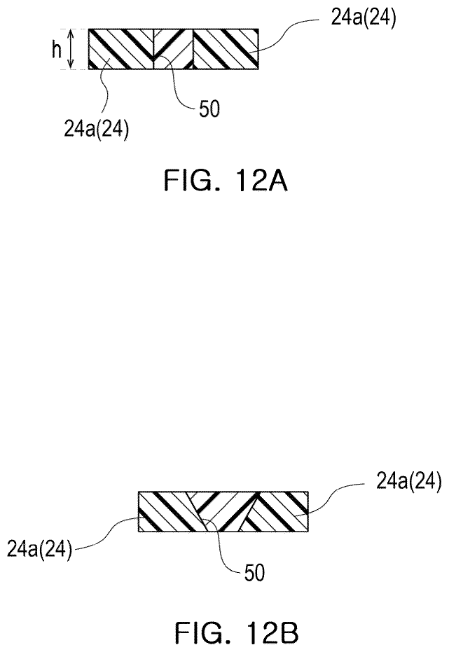

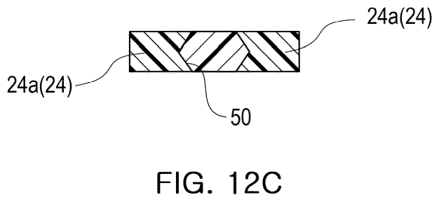

The light separation slit 50 may have any cross-sectional shape that may exert a light-collecting effect, as illustrated in FIGS. 12A to 12C. A cross-sectional shape of the light separation slit 50 cut in a direction in which separated photodiodes 25 are arranged may be, for example, a rectangular shape as illustrated in FIG. 12A, a trapezoid shape as illustrated in FIG. 12B, or a polygonal shape as illustrated in FIG. 12C.

The light separation slit 50 may have a narrow width portion 51 narrower than a wavelength size of the incident light L. The ‘narrow width portion 51’ may refer to a portion of the light separation slit 50 that may be narrow in one direction. Alternatively, ‘the light separation slit 50 has a narrow width portion 51’ may refer to at least a portion of the light separation slit 50 being narrower than a wavelength size of the incident light L. In an example case in which the light separation slit 50 has a rectangular shape as illustrated in FIG. 7A, an elliptical shape as illustrated in FIG. 7D, a cross shape as illustrated in FIG. 9A, or a shape combining a square shape and a cross shape as illustrated in FIG. 9E, a width of an arrow in the drawings may become a narrow width portion 51 narrower than the wavelength size of the incident light L. In this case, a width of the narrow width portion 51 of the light separation slit 50 may refer to a width measured in the horizontal direction or the X-axis direction when the light separation slit 50 is viewed in plan view.

A height (h) of the light separation slit 50 in the stacking direction may be lower than the wavelength size of the incident light L. The light separation slit 50 may have a thickness in the stacking direction smaller than the wavelength size of the incident light L, as illustrated in FIG. 12A, for example. In this case, the thickness in the stacking direction may mean a thickness measured in the vertical direction or the Z-axis direction when the light separation slit 50 is viewed in cross-section.

As described above, in the solid-state image sensor 1, the light separation slit 50 may be formed in the high-refractive index layer 24a of the anti-reflection layer 24 provided on the photodiode 25. The solid-state image sensor 1 may refract the incident light L by a slit structure of the light separation slit 50 to bias light intensity distribution toward the high-refractive index layer 24a. Therefore, the solid-state image sensor 1 may improve a separation ratio.

Next, a description will be given of a modified example of the solid-state image sensor according to an embodiment. The following modified examples may be appropriately incorporated and implemented in the above-described embodiment. In addition, the following modified examples may be appropriately combined and employed in a range not deviated from the gist of the inventive concept of the disclosure.

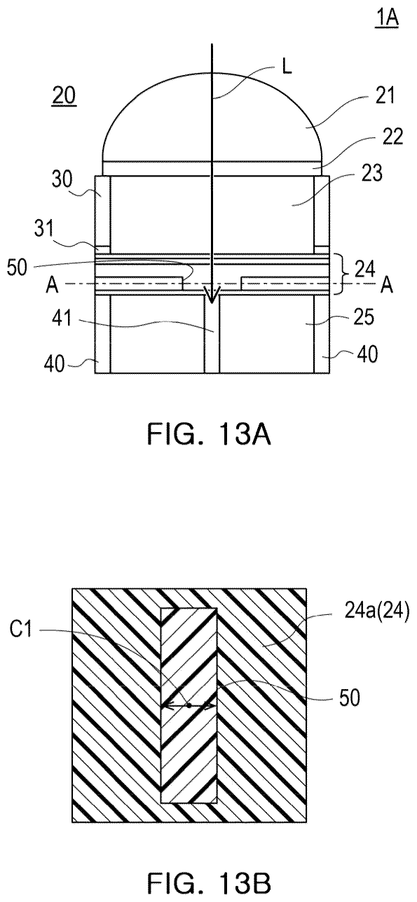

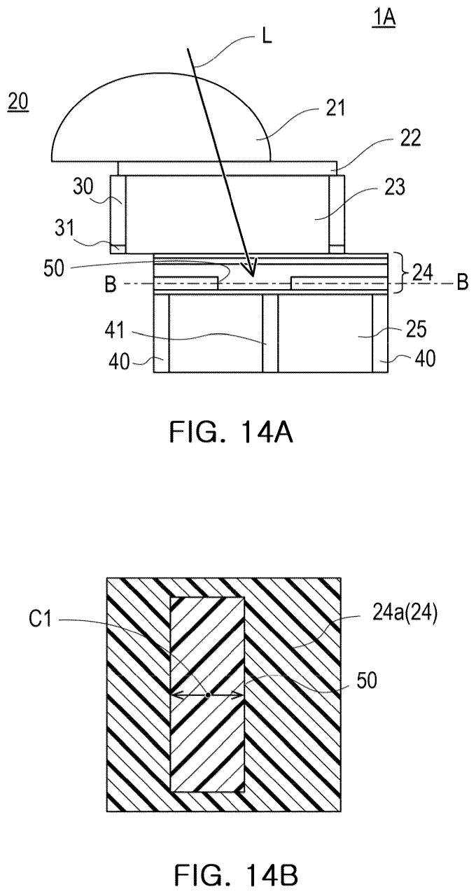

FIG. 13A is a schematic diagram of a phase difference detection pixel 20 provided on a low deviated side in a solid-state image sensor 1A according to an embodiment, and FIG. 13B is a cross-sectional schematic diagram of the phase difference detection pixel 20 illustrated in FIG. 13A, taken along line A-A. FIG. 14A is a schematic diagram of a phase difference detection pixel 20 provided on a high deviated side in a solid-state image sensor 1A according to an embodiment, and FIG. 14B is a cross-sectional schematic diagram of the phase difference detection pixel 20 illustrated in FIG. 14A, taken along line B-B.

As illustrated in FIGS. 13A, 13B, 14A, and 14B, a solid-state image sensor 1A may set a width and/or a center position of a light separation slit 50 when seen from a plane according to a deviated profile from a center of a pixel array 110 of a phase difference detection pixel 20 or a position or a distance away from the center. The ‘phase difference detection pixel 20 provided on a low deviated side’ may refer to a phase difference detection pixel 20 provided in a central portion 110a of the pixel array 110 or adjacent to the central portion 110a, and the ‘phase difference detection pixel 20 provided on a high deviated side’ may refer to a phase difference detection pixel 20 provided in a portion spaced outward from the central portion 110a of the pixel array 110, or adjacent to an outermost periphery of the pixel array 110.

In an example case in which the phase difference detection pixel 20 is provided on a central portion 110a side of the pixel array 110, incident light L may be incident toward a central portion of the phase difference detection pixel 20, as illustrated in FIGS. 13A and 13B. According to an embodiment, as illustrated in FIGS. 13A and 13B, the light separation slit 50 may be arranged such that a center position C1 of the light separation slit 50 is located in the central portion of the phase difference detection pixel 20.

In an example case in which the phase difference detection pixel 20 is provided on a peripheral portion 110b side of the pixel array 110, incident light L may be incident obliquely, as illustrated in FIGS. 14A and 14B. According to an embodiment, the light separation slit 50 may be arranged such that a center position C1 may be shifted in a predetermined direction from a central portion of the phase difference detection pixel 20 in a travel direction of the incident light L, as illustrated in FIGS. 14A and 14B. In addition, as illustrated in FIGS. 14A and 14B, in an example case in which the phase difference detection pixels 20 is provided in a high deviated profile, the light separation slit 50 may be formed with a wide width to match the incident light L to be incident obliquely.

In this manner, the width and/or the center position of the light separation slit 50 in the plane view of the solid-state image sensor 1A may be provided differently depending on a deviated profile from the center of the pixel array 110 in which the phase difference detection pixel 20 is provided. Therefore, since a width or a formation position of the light separation slit 50 may be optimized for various incident angles of the incident light L, the solid-state image sensor 1A may more effectively improve a separation ratio.

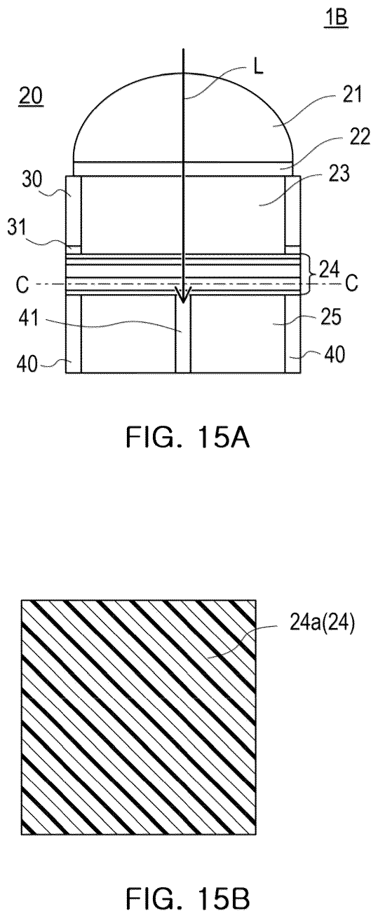

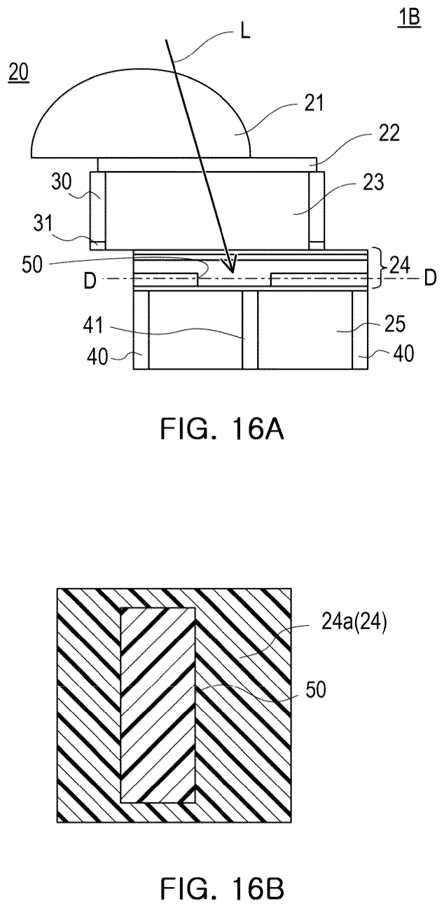

FIG. 15A is a schematic diagram of a phase difference detection pixel 20 provided on a low deviated side in a solid-state image sensor 1B according to another embodiment, and FIG. 15B is a cross-sectional schematic diagram of the phase difference detection pixel 20 illustrated in FIG. 15A, taken along line C-C. FIG. 16A is a schematic diagram of a phase difference detection pixel 20 provided on a high deviated side in a solid-state image sensor 1B according to another embodiment, and FIG. 16B is a cross-sectional schematic diagram of the phase difference detection pixel 20 illustrated in FIG. 16A, taken along line D-D.

As illustrated in FIGS. 15A, 15B, 16A, and 16B, a solid-state image sensor 1B according to another embodiment may form a light separation slit 50 only in a phase difference detection pixel 20 in a position in which separation characteristics requiring pupil correction is likely to deteriorate, depending on an arrangement position of the phase difference detection pixel 20 with respect to a pixel array 110.

The solid-state image sensor 1B may not form the light separation slit 50 because sufficient separation characteristics are obtained in an example case in which the phase difference detection pixel 20 is provided on a central portion 110a side (central region) of the pixel array 110, as illustrated in FIGS. 15A and 15B. The solid-state image sensor 1B may form the light separation slit 50 in an example case in which the phase difference detection pixel 20 is provided on a peripheral portion 110b side (high deviated region) of the pixel array 110 in which separation characteristics are likely to deteriorate, as illustrated in FIGS. 16A and 16B.

In this manner, the solid-state image sensor 1B according to another embodiment forms the light separation slit 50 only in the phase difference detection pixel 20 in a position in which separation characteristics are likely to deteriorate, depending on an arrangement position of the phase difference detection pixel 20 with respect to the pixel array 110. Therefore, since the solid-state image sensor 1B does not need to form the light separation slit 50 in the phase difference detection pixel 20 provided on the central portion 110a side of the pixel array 110 not requiring pupil correction, a structure thereof may be simplified.

Hereinafter, a description will be given of a solid-state image sensor 1C according to another embodiment.

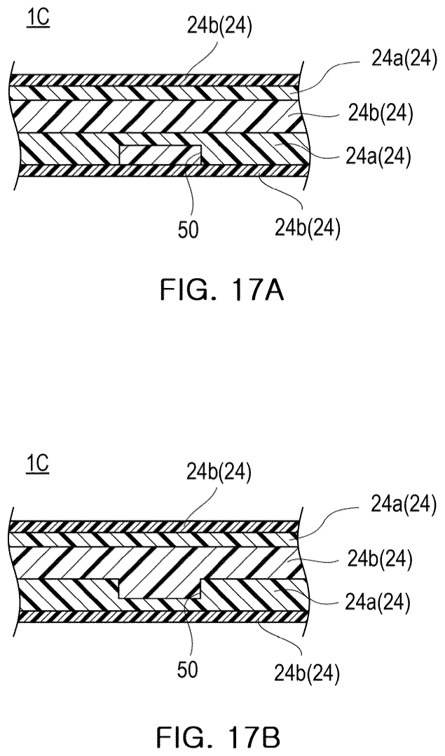

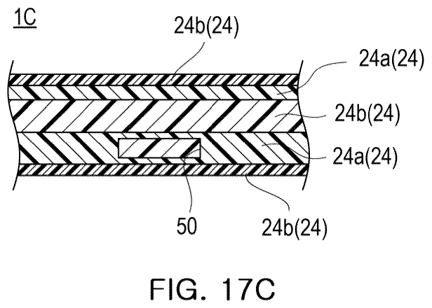

As illustrated in FIGS. 17A to 17C, a solid-state image sensor 1C may be configured to form a light separation slit 50 without penetrating a high refractive index layer 24a in the stacking direction. The solid-state image sensor 1 described above may penetrate a high refractive index layer 24a to be continuous with a low refractive index layer 24b stacked on the high refractive index layer 24a to form a light separation slit 50, but may be different from the previous embodiments in view of the facts that the penetration is not performed.

As illustrated in FIG. 17A, according to an embodiment, a solid-state image sensor 1C may be formed only on a bottom portion (or lower surface side) of a high refractive index layer 24a closest to a photodiode 25. In those illustrated in FIG. 17A, a light separation slit 50 and a lowest low refractive index layer 24b may be formed to be adjacent to each other. As illustrated in FIG. 17A, a thin high refractive index layer 24a may be formed above the light separation slit 50.

In addition, as illustrated in FIG. 17B, according to an embodiment, a solid-state image sensor 1C may be formed only on a ceiling portion (or upper surface side) of a high refractive index layer 24a closest to a photodiode 25. In those illustrated in FIG. 17B, a light separation slit 50 and a low refractive index layer 24b, which may be a third layer in an anti-reflection layer 24 from the bottom, may be formed to be adjacent to each other. In addition, the high refractive index layer 24a having a thin thickness may be formed below the light separation slit 50.

In addition, as illustrated in FIG. 17C, according to an embodiment, a solid-state image sensor 1C may be formed in an intermediate portion of a thickness direction of a high refractive index layer 24a closest to a photodiode 25. In those illustrated in FIG. 17C, a light separation slit 50 may be formed to be surrounded by the high refractive index layer 24a in a vertical direction.

In this manner, the solid-state image sensor 1C according to an embodiment may have a form in which the high refractive index layer 24a is formed in a stacking direction of the light separation slit 50, or is partially left. Therefore, the solid-state image sensor 1C may enhance an anti-reflection function, as compared to a form in which the high refractive index layer 24a is formed by penetrating therethrough, as illustrated in FIG. 3.

As described above, a solid-state image sensor 1 according to the embodiments of the disclosure may be a device having a pixel array 110 in which a plurality of pixels 10 generating an electric signal according to incident light L and at least one phase difference detection pixel 20 are arranged in a two-dimensional shape, wherein the phase difference detection pixel 20 may include a photodiode 25, an on-chip lens 21 provided on an incident side of the incident light L in the photodiode 25, a light-transmitting layer 23 transmitting light of a specific wavelength in the incident light L, an anti-reflection layer 24 stacked on the photodiode 25, a pixel separation pattern 40 provided between the photodiode 25 and a different photodiode 25 of a different pixel 10 adjacent to the photodiode 25, and a boundary separation pattern 41 partitioning the photodiode 25 surrounded by the pixel separation pattern 40 into a plurality of portions, wherein the anti-reflection layer 24 may have a stack structure in which a high refractive index layer 24a and a low refractive index layer 24b are stacked in plural, and wherein the high refractive index layer 24a provided to be closest to the photodiode 25 may have a light separation slit 50 formed of a low-refractive-index material in the high refractive index layer 24a.

By this configuration, the solid-state image sensor 1 may effectively refract incident light L incident obliquely, especially, by a slit structure of the light separation slit 50, to bias light intensity distribution toward the high refractive index layer 24a. Therefore, the solid-state image sensor 1 may improve a separation ratio while reducing light scattering or color mixing due to the pixel separation pattern 40 or the like. In addition, since the solid-state image sensor 1 does not require other additional configurations, such as a light collection lens 200 or the like on the photodiode 25 for improving the separation ratio, the pixel structure may have a low deviated profile. Therefore, the solid-state image sensor 1 may be configured with an on-chip lens 21 having a high radius of curvature, and may reduce a diameter of a light-collecting spot to effectively improve a separation ratio or sensitivity.

Next, examples illustrating one or more embodiments of the disclosure will be described, but the disclosure is not limited to the following examples.

Hereinafter, a simulation was performed to evaluate a separation ratio of phase difference detection pixels for a solid-state image sensor according to an example embodiment of the disclosure (Example Embodiment) and for comparative solid-state image sensor (Comparative Example). In the simulation, quantum efficiency of a green pixel in a photodiode was calculated by a finite-difference time-domain (FDTD) method using Rsoft (manufactured by Synopsys). Incident light of which a wavelength was 530 nm and a incident angle was 10° was introduced.

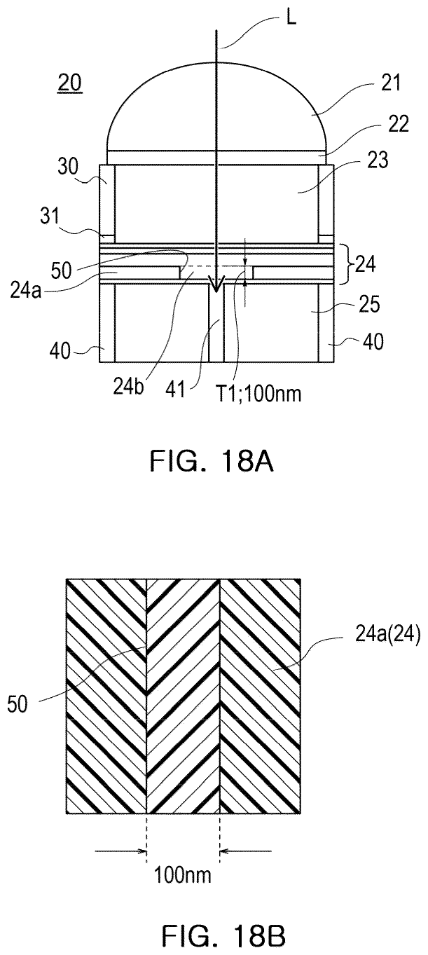

FIG. 18A illustrates a schematic diagram of a solid-state image sensor according to Example Embodiment, and FIG. 18B illustrates a cross-sectional schematic diagram of a high refractive index layer on which a light separation slit is formed in a phase difference detection pixel of Example Embodiment. As illustrated in FIG. 18B, in a sample of Example Embodiment, a light separation slit 50 was formed in a high refractive index layer 24a closest to a photodiode 25 side of an anti-reflection layer 24. In FIG. 18A, a thickness T1 of a high refractive index layer 24a and a thickness T1 of a low refractive index layer 24b of a light separation slit 50 were set to 100 nm, respectively. A width of the light separation slit 50 formed in the high refractive index layer was set to 100 nm. The light separation slit 50 was provided to be parallel to a boundary separation pattern 41 in a plane direction, orthogonal to a stacking direction, in a central portion of a phase difference detection pixel 20.

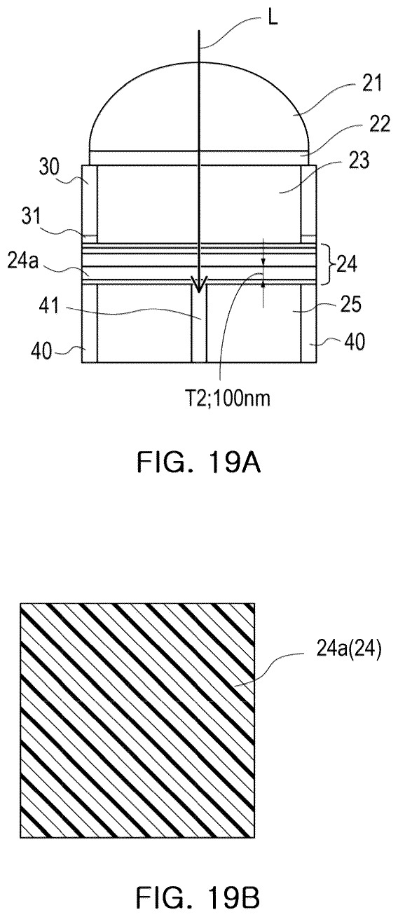

FIG. 19A illustrates a schematic diagram of a solid-state image sensor of Comparative Example, and FIG. 19B illustrates a schematic diagram of a cross-section of a high refractive index layer in a phase difference detection pixel of Comparative Example. As illustrated in FIGS. 19A and 19B, a sample of Comparative Example had a structure of a conventional solid-state image sensor in which a light separation slit 50 was not formed. In FIG. 19A, a thickness T2 of a high refractive index layer 24a was set to 100 nm.

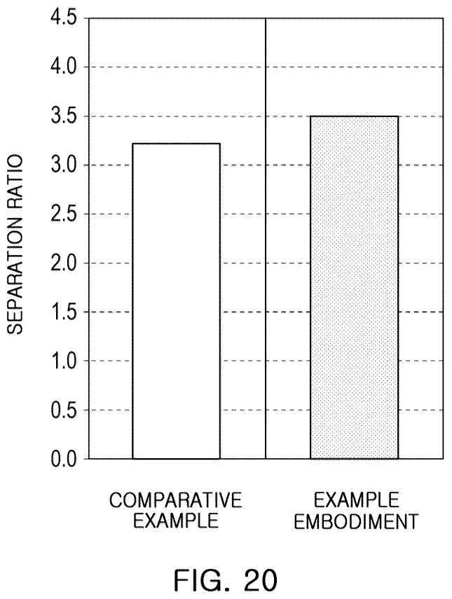

FIG. 20 illustrates a graph illustrating simulation results of separation ratios of Example Embodiment and Comparative Example. As illustrated in FIG. 20, it can be confirmed that a separation ratio of Example Embodiment in which a light separation slit 50 was formed was improved, as compared to Comparative Example in which a light separation slit 50 was not formed.

From the results, it can be seen that, in a solid-state image sensor, in an example case in which the light separation slit was formed in a high refractive index layer provided on a photodiode side, among high refractive index layers constituting an anti-reflection layer of a phase difference detection pixel, incident light L may be effectively refracted and light intensity distribution may be biased toward the high refractive index layer side. Therefore, the light separation slit may be effective in improving the separation ratio while reducing light scattering and color mixing in the phase difference detection pixel.

According to one or more embodiments of the disclosure, a separation ratio of incident light for a phase difference detection pixel may be improved.

While example embodiments have been illustrated and described above, it will be apparent to those skilled in the art that modifications and variations could be made without departing from the scope of the inventive concept of the disclosure as defined by the appended claims.

What is claimed is:

1. A solid-state image sensor comprising:
a substrate comprising a first surface and a second surface opposing the first surface;
a first image pixel comprising a first photodiode (PD);
a second image pixel comprising a second PD;
a phase difference detection pixel comprising a third PD and a fourth PD;
a first lens on the first PD;
a second lens on the second PD;
a third lens on the third PD and the fourth PD;
a boundary separation pattern between the third PD and the fourth PD;
a first separation pattern between the first image pixel and the phase difference detection pixel;
a second separation pattern between the second image pixel and the phase difference detection pixel; and
an anti-reflection layer on the third PD and the fourth PD,
wherein the first image pixel is disposed directly adjacent to the phase difference detection pixel, and the second image pixel is disposed directly adjacent to the phase difference detection pixel,
wherein the anti-reflection layer comprises a high refractive index layer group and a low refractive index layer group,
wherein the high refractive index layer group comprises at least one high refractive index layer and the low refractive index layer group comprises at least one low refractive index layer,
wherein the anti-reflection layer is formed by alternately stacking the at least one high refractive index layer of the high refractive index layer group and the at least one low refractive index layer of the low refractive index layer group,
wherein a first refractive index layer of the high refractive index layer group comprises a light separation slit,
wherein the light separation slit comprises a material having a different refractive index from the first refractive index layer, and
wherein, in a first direction perpendicular to the substrate, the first refractive index layer is the closest to the third PD and the fourth PD among the high refractive index layer group.

2. The solid-state image sensor of claim 1, wherein the light separation slit overlaps with the boundary separation pattern in the first direction.

3. The solid-state image sensor of claim 1, wherein the light separation slit is partially overlapping with both of the third PD and the fourth PD in the first direction.

4. The solid-state image sensor of claim 3, wherein the high refractive index layer group comprises at least two high refractive index layers.

5. The solid-state image sensor of claim 4, wherein the low refractive index layer group comprises at least two low refractive index layers.

6. The solid-state image sensor of claim 5, wherein the boundary separation pattern comprises a first part and a second part spaced apart from the first part in a second direction perpendicular to the first direction and parallel to the first surface in the plan view.

7. The solid-state image sensor of claim 4, wherein a height of the light separation slit in the first direction is smaller than a height of the first refractive index layer in the first direction.

8. The solid-state image sensor of claim 4, wherein the light separation slit is spaced apart from the first separation pattern in a second direction in the plan view.

9. The solid-state image sensor of claim 1, wherein the light separation slit comprises a first part and a second part spaced apart from the first part in a second direction in the plan view.

10. The solid-state image sensor of claim 3, wherein each of the first separation pattern and the second separation pattern is in contact with the second surface, and
wherein the solid-state image sensor is configured to receive light from the second surface.

11. The solid-state image sensor of claim 10, wherein each of the first separation pattern and the second separation pattern penetrates the substrate.

12. The solid-state image sensor of claim 3, wherein the second image pixel is a blue pixel.

13. A solid-state image sensor comprising:
a substrate comprising a first surface and a second surface opposing the first surface;
a phase difference detection pixel comprising a first PD and a second PD;
a separation pattern surrounding the first PD and the second PD in a plan view and in contact with the second surface;
a lens on the first and second PDs;
a boundary separation pattern between the first PD and the second PD; and
an anti-reflection layer on the first PD and the second PD,
wherein the anti-reflection layer comprises a high refractive index layer group and a low refractive index layer group,
wherein the high refractive index layer group comprises at least one high refractive index layer and the low refractive index layer group comprises at least one low refractive index layer,
wherein the anti-reflection layer is formed by alternately stacking the at least one high refractive index layers of the high refractive index layer group and the low refractive index layers of the at least one low refractive index layer group,
wherein a first refractive index layer of the high refractive index layer group comprises a light separation slit,
wherein the light separation slit comprises a material having a different refractive index from the first refractive index layer, and
wherein, in a first direction perpendicular to the substrate, the first refractive index layer is the closest to the first PD and the second PD among the high refractive index layer group.

14. The solid-state image sensor of claim 13, wherein the light separation slit overlaps with the boundary separation pattern in the first direction.

15. The solid-state image sensor of claim 13, wherein the light separation slit is partially overlapping with both of the first PD and the second PD in the first direction.

16. The solid-state image sensor of claim 14, wherein the high refractive index layer group comprises at least two high refractive index layers.

17. The solid-state image sensor of claim 14, wherein the low refractive index layer group comprises at least two low refractive index layers.

18. The solid-state image sensor of claim 14, wherein a height of the light separation slit in the first direction is smaller than a height of the first refractive index layer in the first direction.

19. A solid-state image sensor comprising:
a substrate comprising a first surface and a second surface opposing the first surface;
a phase difference detection pixel comprising a first PD and a second PD;
a lens on the first PD and the second PD;
a boundary separation pattern between the first PD and the second PD;
a separation pattern surrounding the first PD and the second PD in a plan view and in contact with the second surface; and
an anti-reflection layer on the first PD and the second PD,
wherein the anti-reflection layer comprises a first refractive index layer, a second refractive index layer on the first refractive index layer, and a third refractive index layer on the second refractive index layer,
wherein a refractive index of the first refractive index layer is different from a refractive index of the second refractive index layer,
wherein a first refractive index layer comprises a light separation slit,
wherein the light separation slit comprises a material having a different refractive index from the first refractive index layer, and
wherein the light separation slit is overlapping with the boundary separation pattern in a first direction perpendicular to the substrate.

20. The solid-state image sensor of claim 19, wherein the anti-reflection layer further comprises a fourth refractive index layer on the third refractive index layer, and wherein the refractive index of the first refractive index layer is different from a refractive index of the fourth refractive index layer.
